(19) United States
(12) Patent Application Publication
(10) Pub. No.: US 2022/0052295 A1
(43) Pub. Date: Feb. 17, 2022

(54) QUARTER-WAVE OLED

(71) Applicant: Mitchell C. NELSON, Rehoboth, DE (US)

(72) Inventor: Mitchell C. NELSON, Rehoboth, DE (US)

(21) Appl. No.: 14/946,771

(22) Filed: Nov. 19, 2015

Related U.S. Application Data
(60) Provisional application No. 62/082,107, filed on Nov. 19, 2014.
(60) Provisional application No. 62/091,211, filed on Dec. 12, 2014.
(60) Provisional application No. 62/116,137, filed on Feb. 13, 2015.
(60) Provisional application No. 62/161,749, filed on May 14, 2015.
(60) Provisional application No. 62/190,681, filed on Jul. 9, 2015.

(51) Int. Cl. H01L 51/52; H01L 51/44

(52) U.S. Cl. CPC H01L 51/5265; H01L 51/5016; H01L 51/447

(57) ABSTRACT

Embodiments of this invention comprise a lighting device, such as an organic light emitting diode (“OLED”), constructed so as to form a microcavity that is resonant with an emission wavelength of the emitter and with the emitting region located at an antinode of the resonant mode of the cavity. With the emitting region at this location, this resonant mode operates in stimulated emission and causes the excited state population to be locked at a small level. Interference effects may contribute to this by suppressing spontaneous emission into this mode when the emitter is at this location. Because losses are proportional to the excited state population, the losses are constant or near constant while current is increased. Further, because some device degradation processes are also driven by excited state populations, this can extend the device lifetime as well. In addition, instead of charge density building rapidly with current or output, in this invention, charge density is proportional to the square root of current. This removes some important limitations on maximum brightness. In one embodiment, electricity is generated from light, which results in very high efficiency, especially when utilizing spherical microcavities with a distribution of sizes dispersed in another material making up the photovoltaic cell.

### FIELD OF THE INVENTION

This invention relates to devices for converting electricity to light and for converting light to electricity, typically in the form of planar devices or in which nanospheres are dispersed in another material. This invention is an improvement in such devices that reduces or eliminates losses to improve efficiency, maximum output, and lifetime.

### BACKGROUND OF THE INVENTION

Light is a central technology of society, enabling activities at night time and indoors, as well as playing a central role in other technologies including communications, data storage, and medicine, and will likely play a role in quantum computing. Energy consumption for global lighting is said to produce 2 billion tons of $CO_2$ per year, and of that 20\% is said to be produced by 1.6 billion people burning keroosene or paraffin for which they spend 30B USD per year. Efficient production of light therefore contributes to mitigating both climate change and international economic inequality. Similar issues exist in the reverse process for producing electricity from light.

Existing commercial technology for producing light has been unable to achieve high efficiency, and commercial devices in many instances produce excessive waste heat. Organic devices additionally have short lifetimes. Prior art includes devices that use microcavities with a Bragg reflector or dielectric mirror (U.S. Pat. Nos. 5,405,710 and 7,335,921) and that attempt to improve outcoupling with techniques such as lens arrays (US 20140361270). Those improvements do not provide high efficiency at the level of the present invention, they do not prevent efficiency roll off and output roll off, the devices still tend to have short lifetimes compared to other lighting technologies, and they are difficult or comparatively expensive to implement.

What is needed is a device architecture that can be made at comparatively low expense that provides near perfect effficiency with little or no roll-off, little heat waste, and long device lifetime. The invention and claims described here, solves these problems and provides solutions for problems in solar energy generation, and provides a platform for making commercial quantum optical devices.

### OBJECTS OF THE INVENTION

It is an object of this invention to produce light from electricity with high efficiency, little or no efficiency roll-off. little or no efficiency roll-off output roll-off and little or no heat waste, in a way that is comparatively easy to implement and that can be manufactured at comparatively low cost.

Still other objects and advantages of the invention will in part be obvious and will in part be apparent from the specification and drawings.

### SUMMARY OF THE INVENTION

In order to overcome losses in producing light from electricity a lighting device, such as an organic light emitting diode, is constructed so as to form a microcavity that is resonant with an emission wavelength of the emitter and with the emitting region located at an antinode of the resonant mode of the cavity. Normally this resonant mode produces the desired light output of the device. With the emitting region at this location, this mode operates in stimulated emission and causes the excited state population to be locked at a small level. Interference effects may contribute to this by suppressing spontaneous emission into this mode when the emitter is at this location. Since losses are proportional to the excited state population, the losses are constant or near constant while current is increased. Some device degradation processes are also driven by excited state populations, so this can extend the device lifetime as well. Another benefit is that in normal devices, charge density builds rapidly with current or output, in the new device charge density is proportional to the square root of current. This removes some important limitations on maximum brightness.

This same effect can be used in generating electricity from light. Here it results in near perfect efficiency but for practical devices requires spherical microcavities with a distribution of sizes dispersed in another material making up the photovoltaic cell.

### BRIEF DESCRIPTION OF THE DRAWINGS

For a more complete understanding of the invention, reference is made to the following description and accompanying drawings, in which:

FIG. 1 is a simplified example planar Oled Device in schematic; and

FIG. 2 is a simplified Quarterwave Nanosphere in schematic.

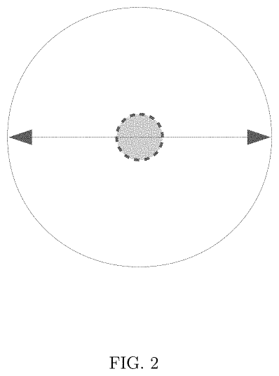

### DETAILED DESCRIPTION OF THE PREFERRED EMBODIMENTS

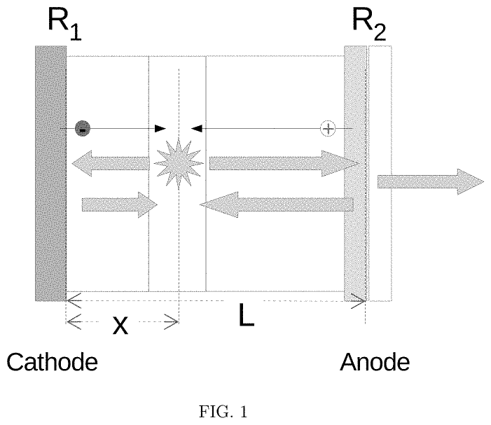

The arrangement in FIG. 1 shows an exemplary arrangement of a simplified planar OLED device. The diagram shows a three layer device with a reflective cathode and a partiall reflective (or partially transparent) anode. The three internal layers are hole transport layer, emitter layer and electron transport layer. Actual devices can have more or fewer layers. The essential aspects of the device are a finite extent emitting region located at the antinode of a resonant cavity. The cavity can have a low finesse and the emitter can have a broad emission.

The normalized magnitude of energy escaping the cavity to the right, is given by

$$\frac{{\vert {E}_{α w} ( λ ) \vert}^{2}}{{\vert {E}_{fvw} ( λ ) \vert}^{2}} = \frac{( 1 - {R}_{2} ) [ 1 + {R}_{1} + 2 \sqrt{{R}_{1}} cos ( 4 π \frac{x ( {λ}_{k} )}{{λ}_{k}} )}{1 + {R}_{1} {R}_{2} - 2 \sqrt{{R}_{1} {R}_{2}} cos ( 4 π \frac{L ( {λ}_{k} )}{{λ}_{k}} )} \qquad ( 1 )$$

where optical lengths L(λ), x(λ), are calculated as

$$L ( {λ}_{k} ) = {\sum }_{i} {n}_{i} ( k ) {L}_{i} + \vert \frac{{ϕ}_{m}}{4 π} {λ}_{k} \vert \qquad ( 2 )$$

where nᵢ and Lᵢ are the index of refraction and thickness of the i-th layer and Oₘ is the phase shift at the mirror,

$${ϕ}_{m} = {tan}^{- 1} ( \frac{2 {n}_{8} {k}_{m}}{{n}_{s}^{2} - {n}_{m}^{2} - {k}_{m}^{2}} ) \qquad ( 3 )$$

where nₘ, kₘ are the real and imaginary indices for the mirror and nₛ is the index of the adjacent organic layer. The optical length x(λ) is calculated including the mirror, intervening layers, and the optical length from the edge of the emitter layer into the emitting region.

In a resonant cavity where one end of the cavity is totally reflective, the normalized amplitude fₖ for emission into mode k is position dependent,

$${f}_{k} ( x ) ∝ 1 + cos [ 4 π \frac{x ( {λ}_{k} )}{{λ}_{k}} ] \qquad ( 4 )$$

where x(λₖ) is the optical distance between the emitting region and mirror. The amplitude for spontaneous emission into mode k is enhanced at x(λₖ)=λₖ/2 and zero at x(λₖ)=λₖ/4. This attenuation to zero for spontaneous emission at the quarter wave location does not depend on the reflectivity of the exit surface or exit mirror. Stimulated emission is not attenuated because the emitted photon is in phase with the stimulating photon.

The lifetime τ_{cav} for a photon to exit the vertical mode of a one wavelength cavity is τ_{cav}=2λ/c(1−R), and the linewidth is Δλ/λ=(½)(1−R). For a low finesse cavity (small R), τ_{cav}˜3×10\hat{ }⁻¹⁵ for λ˜500 nm.

In typical emitter materials, recombination occurs in a region of width wᵣ/d˜4μₕ/(μₑ+μₕ)² centered at xᵣ/d˜μₕ/(μₕ₊μₑ) from the hole injection side within the emitter layer, where μ_{q} are the carrier mobilities and d is the thickness of the emitter layer. Emission occurs within exciton diffusion length of the recombination event.

For purposes of conveying understanding in a simple way, we use as an example an idealized electroluminescent microcavity device with a single excited state and well separated emission and absorption energies, and we begin by describing only the following kinetic processes: recombination, non-radiative relaxation, spontaneous emission and stimulated emission. Non-radiative processes can include any first order loss in the excited state only. The processes are described schematically as,

$$e + h + {N}_{0} {\to }^{{K}_{eh}} N \\ N {\to }^{{K}_{d}} {N}_{0} + e + h \\ N {\to }^{1 / {τ}_{nr}} {N}_{0} + phonon \\ N {\to }^{1 / {τ}_{op}} {N}_{0} + P \\ {P}_{k} + N {\to }^{g} {N}_{0} + 2 {P}_{k} \qquad ( 5 )$$

This device is modeled by the following rate equations for charge density n, excited state population N and photon density P,

$$\begin{matrix}\frac{dn}{dt} = \frac{γ}{{qV}_{o}} I - {K}_{ch} {n}^{2} ( 1 - N ) + {K}_{d} N & ( 6 ) \\ \frac{dn}{dt} = {K}_{ɛ h} {n}^{2} ( 1 - N ) - ( {K}_{d} + \frac{1}{{τ}_{op}} + \frac{1}{{τ}_{nr}} ) N - gPN & ( 7 ) \\ \frac{dP}{dt} = gNP + χ \frac{N}{{τ}_{op}} - \frac{O}{{τ}_{cav}} & ( 8 )\end{matrix}$$

where I is current, γ is the fraction of current that recombines to form excited states, q is the unit charge, Vₐ is volume and Kₑₕ is the rate constant for charge recombination with units chosen such that the ground state population N₀ can be written as N₀=1−N, K_{d} is for charge dissociation from the excited state molecule, τₛₚ is the spontaneous emission lifetime, τₙᵣ is the non radiative lifetime, g is the rate coefficient for stimulated emission, τ_{cav} is the fraction of photons from spontaneous emission that enter the cavity mode, and is the cavity lifetime. Considering all of the modes of the device, χ=f_{k′}/Σₖfₖ where fₖ is the cavity enhancement factor for mode k and k′ is the vertical mode. Setting Σₖfₖ=1, means that 1/τₛₚ is the spontaneous emission rate in the cavity rather than the free space value.

There are two limiting cases for the behavior of the excited state population. When the emitter is at a node, we assume that spontaneous emission is dominant and that light and excited state populations are proportional,

$$\frac{{P}_{SP}}{{τ}_{cav}} = χ \frac{N}{{τ}_{sp}} \qquad ( 9 )$$

When the emitter is at an antinode, for example at x(λ)=λ/4, then χ˜0 and the excited state population is constant,

$${N}_{SE} = \frac{N}{g {τ}_{can}} \qquad ( 10 )$$

Charge density in spontaneous emission is

$${n}_{sp} = \sqrt{\frac{{K}_{d} + 1 / {τ}^{′}}{{K}_{ɛ h}} ( \frac{N}{1 - N} )} \qquad ( 11 )$$

or with equation (6)

$${n}_{sp} = \sqrt{\frac{{K}_{d} {τ}^{′} + 1}{{K}_{c h}} \frac{( γ / {eV}_{a} ) I}{1 / {τ}^{′} - ( γ / {eV}_{a} ) I}} \qquad ( 12 )$$

where 1/τ′=1/τₛₚ+1/τₙᵣ. When charge injection approaches 1/τ′, or as the device approaches saturation in the excited state population, charge density approaches infinity.

Charge density in stimulated emission is

$${n}_{SE} \sim \sqrt{\frac{1}{{K}_{c h}} ( \frac{P}{{τ}_{cav}} + {Λ}_{N} {N}_{SE} )} \qquad ( 13 )$$

where λ_{N}=(K_{d}+1/1/τ′), or in terms of current as

$${n}_{SE} \sim \sqrt{\frac{1}{{K}_{c h}} ( \frac{γ}{{eV}_{a}} I + {K}_{d} {N}_{SE} )} \qquad ( 14 )$$

where N_{SE} is assumed to be small. Charge density in stimulated emission is finite and increases slowly as the square root of current or output.

Voltage is proportional to charge density through an effective capacitance q=C′V, where n=q/Vₐ, C′=(¾)ε/d, V is the voltage across the emitter layer, ε is its dielectric constant and d is its thickness. At low current, the behavior follows a square law in both devices and at higher current, voltage becomes large for the spontaneous emission device.

External efficiency for spontaneous emission is

$${L}_{sp} = γχϕ \frac{1}{q} \qquad ( 15 )$$

where Lₛ, =VₐPₛₚ/τ_{cav} and Φ=(1/τₛₚ/(1/τ′) is the internal quantum yield for radiative relaxation.

External efficiency for stimulated emission is

$${L}_{SE} = \frac{γ}{q} I - {α}_{SE} \qquad ( 16 )$$

where α_{SE}=VₐN_{SE}/τ′.

In spontaneous emission with only first order losses, efficiency is γχΦ≤0.2 for typical devices (apart from the singlet-triplet factor). In stimulated emission efficiency approaches an asymptote at γ, and for modern devices γ˜1.

If the emitter has some spectral overlap, the excited state population may rise to N_{SE}=N′₀+1/g_{cav} where N′₀ is proportional to the overlap and generally small for organics. The asymptotic efficiency is still γ.

Maximum output in these simplified devices is defined in terms of a limiting charge density nₗᵢₘ that depends on the emitter material. Then, for spontaneous emission,

$$\frac{{P}_{sp}}{{τ}_{cav}} {<}_{\sim} χϕ \frac{{K}_{eh} {n}_{lim}^{2}}{1 + {K}_{ch} {τ}^{′} {n}_{lim}^{2}} \qquad ( 17 )$$

or with Kₑₕτ′˜1,

$$\frac{{P}_{sp}}{{τ}_{cav}} ≲ χϕ {K}_{eh} \frac{{n}_{lim}^{2}}{1 + {n}_{lim}^{2}} \qquad ( 18 )$$

In stimulated emission,

$$\frac{{P}_{SE}}{{τ}_{cav}} \leq {K}_{eh} {n}_{lim}^{2} ( 1 - {N}_{SE} ) \qquad ( 19 )$$

Output from spontaneous emission is reduced by another factor ½ by choosing materials with high n²ₗᵢₘ, while output from stimulated emission is enhanced by this strategy. Also, in phosphorescent devices the limit for a spontaneous emission device is reduced to χφτ_{fl}/τₚₕ˜10⁻³-10⁻⁶, while the use of a phosphorescent emitter does not change the limit for a stimulated emission device.

The two device configurations are summarised in Table 0.1. In the spontaneous emission device output is proportional to the excited state population, charge density and voltage approach infinity for finite output, and efficiency is limited by outcoupling and internal losses. In the stimulated emission device, the excited state population is held constant while charge density and voltage increase slowly and remain finite for finite output, and efficiency approaches 1.

TABLE 0.1
Comparison of properties of spontaneous emission devices and
stimulated emission devices with loss terms to first order in N.

| Property | Spontaneous Em. | Stimulated Em. |
|---|---|---|
| N | I, L | constant |
| n, [symbol] | $\sqrt{\frac{I}{1 / {τ}^{′} - I}}$ | \sqrt{I} |
| EQE (L/I) | γ χ ϕ | γ (~1) |
| Lₘₐₓ(fl) | $γ χ ϕ {K}_{eh} \frac{{n}_{lim}^{2}}{1 + {u}_{lim}^{2}}$ | Kₑₕ nₗᵢₘ² |

In an actual device, light might first appear at low current through stimulated emission and then the device transitions to stimulated emission. This can produce an apparent change in a parameter associated with charge mobility. This is explained in the following paragraphs.

The device capacitance is modeled as two capacitors in series $1/C′=1/Cₑ+1/Cₕ where C_{e,h}=(¾)ε/x_{e,h} and x_{e,h}=(μ_{e,h}/μₕ+μₑ)d are the capacitances and widths of two adjacent regions for electrons, and for holes, C is the dielectric constant, d is the total thickness of the layer and μ_{q} are the charge carrier mobilities.

Charge carrier mobilities enter into the kinetic rate constant for recombination,

$${K}_{eh} = \frac{q}{ϵ} ( {μ}_{e} + {μ}_{h} ) \qquad ( 20 )$$

At low current this gives us the well studied Mott-Gurney behavior for current and voltage in OLEDs,

$$I = \frac{9}{8} ϵ ( {μ}_{e} + {μ}_{h} ) {𝕍}^{2} / {d}^{3} \qquad ( 21 )$$

Charge carrier mobilities follow a Poole-Frenkel law,

$${μ}_{q} = {μ}_{q} ( 0 ) exp [ α \sqrt{𝕍 / d} ] \qquad ( 22 )$$

In the spontaneous emission case,

$$N = \frac{{K}_{eh} {n}^{2}}{{K}_{eh} {n}^{2} + 1 / {τ}^{′}} \qquad ( 23 )$$

For small n we can use the approximation N≈K_{ehτ}′n², and from equation (6) we have

$$\frac{γ}{e {V}_{a}} I = {K}_{eh} {n}^{2} - {( {K}_{eh} )}^{2} {τ}^{′} {n}^{4} \qquad ( 24 )$$

We write this in terms of the mobilities and Poole-Frenkel dependence using equation (20) and equation (22),

$$\frac{γ}{e} I = {μ}_{0}^{2} {e}^{2 α \sqrt{{V}_{0}}} ( \frac{{e}^{- α \sqrt{{𝕍}_{0}}}}{{μ}_{0}} - {τ}^{′} {𝕍}_{0}^{2} ) {𝕍}_{0}^{2} \qquad ( 25 )$$

where μ₀=μₑ(0)+μₕ(0).

The coefficient α is found from I-V data by graphing log I/V² versus VV. For our spontaneous emission device, we expect

$$log ( \frac{I}{{𝕍}_{0}^{2}} ) = 2 α \sqrt{{𝕍}_{0}} + log ( {μ}_{0}^{2} ( e {V}_{a} / γ ) ( \frac{{e}^{- α \sqrt{{𝕍}_{0}}}}{{μ}_{0}} - {τ}^{′} {𝕍}_{0}^{2} ) ) \qquad ( 26 )$$

The second term is small and the graph of log(I/V₀²) versus √V will approximate a straight line with slope 2α.

For a stimulated emission device, N=N_{SE} is constant,

$$\frac{γ}{e {V}_{a}} \frac{I}{{𝕍}^{2}} = {μ}_{0} {e}^{α \sqrt{V}} {C}^{2} ( 1 - {N}_{SE} ) \qquad ( 27 )$$

and for our M-G plot we have

$$log ( \frac{I}{{𝕍}^{2}} ) = α \sqrt{𝕍} + log ( \frac{e {V}_{a}}{γ} {μ}_{0} {C}^{2} ( 1 - {N}_{SE} ) \qquad ( 28 )$$

Graphing log(I/V₀²) versus √V we find a slope of α for stimulated emission.

This provides a signature for the transition from spontaneous emission to stimulation emission at low voltage. The coefficient α changes downward. The factor of 2 may be approximate.

Second order losses are added to our model by adding a term to the rate equation for N. For clarity we set aside dissociation losses and focus only on the second order losses. The steady state solutions for current, charge, and excited state population are,

$$\begin{matrix}\frac{γ}{e {V}_{a}} I = {K}_{eh} {n}^{2} ( 1 - N ) & ( 29 ) \\ {K}_{eh} {n}^{2} ( 1 - N ) = {K}_{TT} {N}^{2} - ( \frac{1}{{τ}^{′}} + gP ) N & ( 30 )\end{matrix}$$

For spontaneous emission we have,

$$\frac{{P}_{sp ( q )}}{{τ}_{cav}} + {K}_{TT} \frac{{τ}_{sp} {τ}^{′}}{χ} {( \frac{P}{{τ}_{cav}} )}^{2} = χ ϕ \frac{γ}{e {V}_{a}} I \qquad ( 31 )$$

At high output Lα√{I/\K_{TT}} while efficiency falls off as 1/√I, and, the charge limited output is P/τ_{cav}≤(χ/τₛₚ)(√(Kₑₕ/K_{TT}})nₗᵢₘ. The efficiency roll-off is small unless K_{TT} is large, and, the second order loss term does not produce output roll-off.

For stimulated emission,

$$\frac{{P}_{sp ( q )}}{{τ}_{cav}} = \frac{γ}{e {V}_{a}} I - {α}_{q} \qquad ( 32 )$$

where α_{q}=N_{SE}/τ′+K_{TT}N_{SE}². Output remains linear in current and efficiency increases approaching an asymptote at γ. The charge limited output is P/τ_{cav}≤Kₑₕnₗᵢₘ².

Loss mechanisms of the form nN, can be described schematically as

$$\begin{matrix}n + N {⟶}^{{K}_{nN}} {N}_{0} + {n}^{*} & ( 33 ) \\ {n}^{*} {⟶}^{1 / {τ}_{n}} n & ( 34 )\end{matrix}$$

where n refers to parked charge or a species such as a polaron with population proportional to charge. The rate equations for n, N and n* are

$$\begin{matrix}\frac{dn}{dt} = \frac{γ}{e {V}_{a}} I - {K}_{ch} {n}^{2} ( 1 - N ) - {K}_{n} nN + \frac{1}{{τ}_{n}} {n}^{*} & ( 35 ) \\ \frac{dN}{dt} = {K}_{ch} {n}^{2} ( 1 - N ) - {K}_{n} nN - ( \frac{1}{{τ}^{′}} - gP ) N & ( 36 ) \\ \frac{{dn}^{*}}{dt} = {K}_{n} nN - \frac{1}{{τ}_{n}} {n}^{*} & ( 37 )\end{matrix}$$

For spontaneous emission the light current relationship is

$$\begin{matrix}\frac{P}{{τ}_{\text{?}}} = χϕ \frac{γ}{e {V}_{a}} I ( \frac{1}{{K}_{\text{?}} {τ}^{′} n + 1} ) & ( 38 ) \\ \text{?} \text{indicates text missing or illegible when filed} & \end{matrix}$$

Output is attenuated as charge builds up. It is easily shown that this loss term produces efficiency roll off.

For stimulated emission the light-current relationship is

$$\begin{matrix}\frac{{P}_{SE ( nN )}}{{τ}_{\text{?}}} = \frac{γ}{e {V}_{a}} I - {α}_{SE} / {V}_{a} - {K}_{n} {nN}_{SE} & ( 39 ) \\ \text{?} \text{indicates text missing or illegible when filed} & \end{matrix}$$

Output is approximately linear since the loss term is scaled by N_{SE}, grows slowly as √I. The maximum output in stimulated emission with polaron quenching is still ˜$Kₑₕnₗᵢₘ².

Charge bleaching where recombined charges interact with an excited state species, can be depicted schematically as,

$$\begin{matrix}e + h + N {\to }^{{K}_{ch ( 2 )}} {N}_{2} & ( 40 ) \\ {N}_{2} {\to }^{1 / \text{?}} {N}_{0} & ( 41 ) \\ \text{?} \text{indicates text missing or illegible when filed} & \end{matrix}$$

where N₂ is a doubly excited state. The rate equations are changed to

$$\begin{matrix}\frac{dn}{dt} = \frac{γ}{q {V}_{a}} I - {K}_{ch} {n}^{2} ( 1 - N - {N}_{2} ) - {K}_{ch ( 2 )} {n}^{2} N & ( 42 ) \\ \frac{dN}{dt} = {K}_{ch} {n}^{2} ( 1 - N - {N}_{2} ) - ( {K}_{ch ( 2 )} {n}^{2} + \frac{1}{{τ}^{′}} + gP ) N & ( 43 ) \\ \frac{{dN}_{2}}{dt} = {K}_{ch ( 2 )} {n}^{2} N - \frac{1}{{τ}_{( 2 )}^{′}} {N}_{2} & ( 44 )\end{matrix}$$

For spontaneous emission the relationship between current and light becomes

$$\begin{matrix}\frac{{P}_{sp}}{{τ}_{\text{?}}} = χ ( \frac{1 / {τ}_{sp}}{1 / {τ}^{′} + 2 {K}_{ch ( 2 )} {n}^{2}} ) \frac{γ}{e {V}_{a}} I & ( 45 ) \\ \text{?} \text{indicates text missing or illegible when filed} & \end{matrix}$$

For stimulated emission we obtain,

$$\begin{matrix}\frac{{P}_{SE}}{{τ}_{\text{?}}} = \frac{γ}{e {V}_{a}} I - ( \frac{1}{{τ}^{′}} + {K}_{ch ( 2 )} {n}^{2} ) {N}_{SE} & ( 46 ) \\ \text{?} \text{indicates text missing or illegible when filed} & \end{matrix}$$

and light is nearly linear in current. Again the loss terms are scaled by N_{SE}.

This loss terms introduces a local maximum in output at finite charge or current. For spontaneous emission, charge is related to current by

$${N}_{sp} = \frac{{K}_{ch} {n}^{2}}{{K}_{ch} {K}_{ch ( 2 )} {τ}_{( 2 )}^{′} {n}^{4} + ( {K}_{ch} + {K}_{ch ( 2 )} ) {n}^{2} + 1 / {τ}^{′}} \qquad ( 47 )$$

and therefore Nₛₚ now has a maximum at

$${n}_{sp ( ma x )}^{2} = \frac{1}{\sqrt{2 {K}_{ch} {τ}^{′} {K}_{ch ( 2 )} {τ}_{( 2 )}^{′}}} \qquad ( 48 )$$

and the maximum output from spontaneous emission is then

$$\begin{matrix}\frac{{P}_{sp .}}{{τ}_{\text{?}}} \leq \frac{1}{2} χϕ ( \frac{{K}_{ch}}{( {K}_{ch} + {K}_{ch ( 2 )} ) {τ}^{′} + \sqrt{2 {K}_{ch } {τ}^{′} {K}_{ch ( 2 )} {τ}_{( 2 )}^{′}}} ) & ( 49 ) \\ \text{?} \text{indicates text missing or illegible when filed} & \end{matrix}$$

The stimulated emission device has P related to n by

$$\begin{matrix}\frac{{P}_{SE}}{{τ}_{\text{?}}} = [ {K}_{ch} ( 1 - {N}_{SE} ) - {K}_{ch ( 2 )} {N}_{SE} ] {n}^{2} - {K}_{ch} {K}_{ch ( 2 )} {τ}_{( 2 )}^{′} {N}_{SE} {n}^{4} & ( 50 ) \\ \text{?} \text{indicates text missing or illegible when filed} & \end{matrix}$$

which gives a maximum for P at

$${n}_{SE ( ma x )}^{2} = \frac{1}{2} ( \frac{1 - {N}_{SE}}{{N}_{SE}} - \frac{{K}_{ch ( 2 )}}{{K}_{ch}} ) \frac{1}{{K}_{ch ( 2 )} {τ}_{( 2 )}^{′}} \qquad ( 51 )$$

For small N_{SE}, n˜(1/√{2N_{SE}) (1/Kₑₕ₍₂₎τ₍₂₎) and

$$\begin{matrix}\frac{{P}_{SE}}{{τ}_{\text{?}}} ≲ \frac{1}{4} \frac{{K}_{ch}}{{K}_{ch ( 2 )} {τ}_{( 2 )}^{′}} \frac{{( 1 - {N}_{SE} )}^{2}}{{N}_{SE}} & ( 52 ) \\ \text{?} \text{indicates text missing or illegible when filed} & \end{matrix}$$

The maximum will generally occur well beyond operating conditions, so stimulated emission has effectively removed this limit.

The above analysis can be extended to include three level systems where there are singlet and triplet excited states, and donor-acceptor systems where there are multiple molecular or polymer components in the emitter. In a wide variety of those systems, high efficiency and high output can be produced by locating the emitter at an antinode in a mode connected to a radiative transition in the material. For example, configuring the device so that stimulated emission occurs in the triplet to ground state transition, causes both the singlet and triplet state to ground transitions to have linear output.

The device might also be implemented in a spherical microcavity where the emitter and antinode are located at the center of a sphere of diameter one half wavelength or odd multiple of a half wavelength, or where the emitter and antinode are located in a shell at some radius within the device. In either implementation the device has spherical symmetry or an approximation thereof. We will call this a quarter wave sphere (QWS)

QWS's might be dispersible in a carrier or liquid for making OLEDs from liquid deposition. QWS's can be produced in a distribution of sizes as a way to broaden the spectrum of the device.

Planar quarter wave devices and QWS's can each be used in photovoltaics where the antinode location of the photoelectric material suppresses recombination losses. The spherical symmetry of QWS provides isotropic absorption of light and a distribution of sizes facilitates broad band absorption.

In photovoltaics we have generation of free carriers which can come off as an electric current in competition with formation of charge transfer states which can dissociate back to free charge or recombine and re-emit light.

We write rate equations for production of free charge which is lost to current and to forming charge transfer states (formed at a donor-acceptor interface) which then recombine and emit light or dissociate to return charge back to the free carrier population.

$$\begin{matrix}\frac{d [ n ]}{dt} = G [ P ] - I - {{K}_{ch} [ n ]}^{2} & ( 53 ) \\ \frac{d [ {N}_{CT} ]}{dt} = {{K}_{ch} [ n ]}^{2} - ( {K}_{T} + {K}_{d} ) [ {N}_{CT} ] & \end{matrix}$$

where G is the charge production rate from light, I is the current produced by the device, Kₘ is the recombination rate, K_{d} is the dissociation rate, and K_{T} is the relaxation rate from the charge transfer state to emit photons. In steady state we have

$$I = G - {( 1 - \frac{{K}_{d}}{{K}_{T} + {K}_{d}} ) [ n ]}^{2} \qquad ( 54 )$$

In a quarter wave device, K_{T}˜0, and the efficiency for producing current becomes 100%.

It will thus be seen that the objects set forth above, among those made apparent from the preceding description, are efficiently attained and, because certain changes may be made in carrying out the above method and in the construction(s) set forth without departing from the spirit and scope of the invention, it is intended that all matter contained in the above description and shown in the accompanying drawings shall be interpreted as illustrative and not in a limiting sense.

It is also to be understood that the following claims are intended to cover all of the generic and specific features of the invention herein described and all statements of the scope of the invention which, as a matter of language, might be said to fall therebetween.

What is claimed is:

1. A device comprising a cavity; an emitting region within the cavity, the emitting region capable of emitting a wavelength; and a first surface which is reflective.

2. The device as described in claim 1 in which the first surface is separated from the emitting region by an approximate optical distance of an odd multiple of one-quarter of the wavelength.

3. The device as described in claim 2 further comprising a second surface which is separated from the first surface by an approximate optical distance of a multiple of one-half of the wavelength.

4. The device as described in claim 3 wherein the emitting region comprises electroluminescent material.

5. The device as described in claim 4 where the device further comprises an electrode to inject electrical current into the device.

6. The device as described in claim 5 where the device further comprises a layer to facilitate transport or blocking of an electrical carrier.

7. The device as described in claim 3 where the second surface is either reflective or partially transparent.

8. The device as described in claim 3 wherein the device comprises an organic light emitting diode (“OLED”).

9. The device as described in claim 1 wherein the surface of the cavity is spherical or ellipsoidal in shape.

10. The device as described in claim 9 wherein the emitting region is located at the center or at approximately an optical distance of an odd multiple of one quarter wavelength from the surface of the cavity.

11. The device as described in claim 10 in which the device is dispersed in another material.

12. The device as described in claim 3 in which the emitting region produces a charge carrier in response to light.

13. The device as described in claim 12 wherein the device further comprises an electrode to extract electrical current from the device.

14. The device as described in claim 13 wherein the device further comprises an additional layer to facilitate extraction of electrical current from the device.

15. The device as described in claim 3 wherein the device comprises a photovoltaic device.

16. The device as described in claim 1 in which the emitting region produces a charge carrier in response to light; the surface of the cavity is spherical or ellipsoidal in shape; and the emitting region is located at the center or at approximately an optical distance of an odd multiple of one quarter wavelength from the surface of the cavity.

17. The device as described in claim 16 in which the device is dispersed in another material.

18. An electroluminescent device comprising a resonant cavity with an emitter, in which there is low spectral overlap between emission and absorption in the emitter; a first surface which is reflective; and
a second surface which is partially reflective.

19. The device as described in claim 18, in which the emitter is phosphorescent.

20. The device as described in claim 18, in which a state of the emitter is not populated.

21. A method of detecting stimulated emission in a device having spontaneous emission, the method comprising the steps of (a) determining a voltage across an emitter layer of the device (“V”); (b) determining a transition between the spontaneous emission and the stimulated emission in the device; and (c) observing or detecting a change in the slope of $log(I/V\hat{ }2)$ versus $\sgrt{V}$ associated with the transition.
